(19) United States
(12) Patent Application Publication
(10) Pub. No.: US 2004/0084146 A1
(43) Pub. Date: May 6, 2004

(54) Plasma treatment apparatus, upper electrode cover, and upper electrode cover window member

(75) Inventor: Chikako Sekiya, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/611,866

(22) Filed: Jul. 3, 2003

(30) Foreign Application Priority Data
Jul. 4, 2002 (JP) 2002-195708

(51) Int. Cl. H01L 21/306

(52) U.S. Cl. 156/345.24

(57) ABSTRACT

There is provided a plasma treatment apparatus according to which an upper electrode cover window member can easily be replaced, and hence the cost of maintenance of the plasma treatment apparatus can be reduced. A plasma treatment apparatus 1 has a plasma treatment vessel 2 that is made of an electrically conductive material and has an internal chamber 15 in an upper portion thereof, an upper electrode 12 that is disposed in an upper portion of the internal chamber 15, and an internal viewing tube 100 that is provided in the upper electrode 12. The upper electrode 12 is comprised of an upper electrode main body 32, and an upper electrode cover 31 that is for isolating the upper electrode main body 32 from a plasma region 41 formed inside the internal chamber 15. The upper electrode cover 31 has a hole formed therein at a location corresponding to an opening 32a in the upper electrode main body 32, and a window member 31a that is comprised of a transparent member and has a shape complementary to that of the hole is fitted into the hole.

### BACKGROUND OF THE INVENTION

1. Field of the Invention

The present invention relates to a plasma treatment apparatus, an upper electrode cover, and an upper electrode cover window member.

2. Description of the Related Art

These days, in semiconductor device manufacturing processes, plasma treatment such as etching, sputtering, and CVD (chemical vapor deposition) is carried out on semiconductor wafers as articles to be treated.

Various types of plasma treatment apparatus are used for carrying out such plasma treatment, but parallel plate plasma treatment apparatuses are particularly commonly used. Such a parallel plate plasma treatment apparatus is comprised of a cylindrical vacuum vessel having therein an internal chamber in which plasma treatment is carried out on a semiconductor wafer, and a pair of parallel plate electrodes, specifically an upper electrode that is disposed in an upper portion of the internal chamber and a lower electrode that is disposed in a lower portion of the internal chamber.

A semiconductor wafer is placed on the lower electrode so as to face the upper electrode, and the plasma with which the semiconductor wafer is treated is produced by introducing a treatment gas into the internal chamber and applying a high-frequency electric field between the parallel plate electrodes, whereby a plasma region is formed in the internal chamber.

The upper electrode disposed in the upper portion of the internal chamber is comprised of an upper electrode main body made of a metal such as Al, and an upper electrode cover made of quartz that is joined to a lower surface of the upper electrode main body, for isolating the upper electrode main body from the plasma region formed in the internal chamber.

When etching a film such as an oxide film on a semiconductor wafer using the parallel plate plasma treatment apparatus, the inside of the internal chamber is put into a medium pressure state, and a plasma of medium density is produced, whereby optimum radical control is made possible, and hence a suitable plasma state can be obtained. As a result, semiconductor wafer etching with a high degree of stability and reproducibility can be realized.

With such a parallel plate plasma treatment apparatus, the extent of progress of the etching is detected via an internal viewing tube provided in the upper electrode as shown in FIG. 6, described below.

FIG. 6 is a sectional view of an internal viewing tube provided in the upper electrode in a conventional plasma treatment apparatus.

In FIG. 6, a vacuum vessel 52 has therein an upper electrode main body 50, which is disposed above a lower electrode. An upper electrode cover 51 is joined to a lower surface of the upper electrode main body 50 so as to isolate the upper electrode main body 50 from a plasma region 70 formed inside the internal chamber. An internal viewing tube 80 is comprised of a sensor mount 54 that is provided on the vacuum vessel 52 above an opening 50a provided in the upper electrode main body 50, has a hole formed in a central portion thereof, and has a sensor, not shown, mounted thereon, and a tubular member 55 that is provided in the vacuum vessel 52 with its lower end inserted in the opening 50a, and connects the opening 50a and the hole of the sensor mount 54 together. An optical glass member 53 made of quartz or the like is fitted into the hole of the sensor mount 54.

Light emitted by the sensor passes through the optical glass member 53 and enters the vacuum vessel 52. This light passes through a circular transparent window member formed integrally with the upper electrode cover 51 that is formed of a transparent disk-shaped member, and reaches a semiconductor wafer 60. The light is reflected by the semiconductor wafer 60, and then the reflected light passes through the window member of the upper electrode cover 51 and the optical glass member 53, and reaches the sensor.

The sensor detects changes in the intensity of the reflected light, thus detecting the extent of progress of the etching.

However, as the semiconductor wafer 60 etching progresses, once the time period of application of the high-frequency electric field has reached approximately 50 to 70 hours, fogging up of the upper electrode cover 51, in particular the transparent window member, occurs. A problem has thus arisen in that it becomes impossible for the sensor to detect changes in the intensity of the reflected light, and hence the extent of progress of the etching of the semiconductor wafer 60 cannot be detected.

To resolve this problem, once the light intensity has reached the minimum limit of detection, maintenance is carried out in which the upper electrode cover 51 is replaced. However, in this maintenance, the whole of the upper electrode cover 51 having the transparent window member integrally formed therewith must be replaced with a new one, resulting in an increase in cost.

### SUMMARY OF THE INVENTION

It is an object of the present invention to provide a plasma treatment apparatus, an upper electrode cover, and an upper electrode cover window member, according to which the upper electrode cover window member can easily be replaced, and hence the cost of maintenance of the plasma treatment apparatus can be reduced.

To attain the above object, in a first aspect of the present invention, there is provided a plasma treatment apparatus comprising a vacuum vessel that houses an article to be treated and into which a treatment gas is introduced, a lower electrode that is provided inside the vacuum vessel and onto which is placed the article to be treated, an upper electrode main body that is provided above the lower electrode to form a plasma region in the vacuum vessel, the upper electrode main body having formed therein an opening through which passes light for detecting an extent of progress of plasma treatment of the article to be treated in the plasma region, an upper electrode cover that is joined to a lower surface of the upper electrode main body, the upper electrode cover having formed therein a hole at a location corresponding to the opening of the upper electrode main body, and a window member fitted in the hole of the upper electrode cover.

According to this construction, the upper electrode cover has formed therein a hole at a location corresponding to the opening of the upper electrode main body, and a window member fitted in the hole of the upper electrode cover. As a result, an upper electrode cover window member can be fitted into the hole, and hence if fogging up of the upper electrode cover window member occurs, it is not necessary to remove the whole of the upper electrode cover, but rather it is easy to replace only the upper electrode cover window member, and hence the cost of maintenance of the plasma treatment apparatus can be reduced.

To attain the above object, in a second aspect of the present invention, there is provided an upper electrode cover for a plasma treatment apparatus, the plasma treatment apparatus comprising a vacuum vessel that houses an article to be treated and into which a treatment gas is introduced a lower electrode that is provided inside the vacuum vessel and onto which is placed the article to be treated, and an upper electrode main body that is provided above the lower electrode to form a plasma region in the vacuum vessel, the upper electrode main body having formed therein an opening through which passes light for detecting an extent of progress of plasma treatment of the article to be treated in the plasma region, wherein the upper electrode cover has formed therein a hole in which a window member is to be fitted, at a location corresponding to the opening in the upper electrode main body, the hole having a shape complementary to a shape of the window member.

According to this construction, the upper electrode cover has formed therein a hole in which a window member is to be fitted, at a location corresponding to the opening in the upper electrode main body, and the hole has a shape complementary to a shape of the window member. As a result, it is easy to replace only the window member, and hence the cost of maintenance of the plasma treatment apparatus can be reduced.

Preferably, the hole has a lower portion having a reduced diameter and an upper portion having an increased diameter.

Preferably, the hole opens into the plasma region.

Preferably, the upper electrode cover is made of quartz.

To attain the above object, in a third aspect of the present invention, there is provided an upper electrode cover window member for a plasma treatment apparatus, the plasma treatment apparatus comprising a vacuum vessel that houses an article to be treated and into which a treatment gas is introduced a lower electrode that is provided inside the vacuum vessel and onto which is placed the article to be treated, an upper electrode main body that is provided above the lower electrode to form a plasma region in the vacuum vessel, the upper electrode main body having formed therein an opening through which passes light for detecting an extent of progress of plasma treatment of the article to be treated in the plasma region, and an upper electrode cover that is joined to a lower surface of the upper electrode main body, wherein the upper electrode cover window member comprises a transparent member that has at least in part a shape complementary to a shape of a hole formed in the upper electrode cover at a location corresponding to the opening in the upper electrode main body such that the upper electrode cover window member can be fitted in the hole.

According to this construction, the upper electrode cover window member comprises a transparent member that has at least in part a shape complementary to a shape of a hole formed in the upper electrode cover at a location corresponding to the opening in the upper electrode main body such that the upper electrode cover window member can be fitted in the hole. As a result, if fogging up of the upper electrode cover window member occurs, it is not necessary to remove the whole of the upper electrode cover, but rather it is easy to replace only the upper electrode cover window member, and hence the cost of maintenance of the plasma treatment apparatus can be reduced.

Preferably, the hole has a lower portion having a reduced diameter and an upper portion having an increased diameter, and the upper electrode cover window member has a lower portion having a reduced diameter and an upper portion having an increased diameter that can be fitted in the lower portion and upper portion of the hole, respectively.

Alternatively, the hole has a lower portion having a reduced diameter and an upper portion having an increased diameter, and the upper electrode cover window member presents a vertically symmetrical shape having a lower portion having a reduced diameter, an intermediate portion having an increased diameter, and an upper portion having a reduced diameter that can be fitted in the lower portion of the hole, the opening in the upper electrode main body, and the upper portion of the hole, respectively. As a result, the upper electrode cover window member can be installed into the hole of the upper electrode cover either way up, i.e. no problem will arise if the upper electrode cover window member is installed upside down.

Preferably, The upper electrode cover window member is made of quartz.

Alternatively, instead of quartz, the upper electrode cover window member is made of sapphire. As a result, the plasma resistance of the upper electrode cover window member can be improved, and hence the lifetime of the upper electrode cover window member can be lengthened; the frequency of replacement of the upper electrode cover window member can thus be reduced. The above and other objects, features, and advantages of the invention will become more apparent from the following detailed description taken in conjunction with the accompanying drawings.

### BRIEF DESCRIPTION OF THE DRAWINGS

FIG. 1 is a schematic sectional view showing the construction of a plasma treatment apparatus according to an embodiment of the present invention;

FIG. 2 is a sectional view of an internal viewing tube provided in an upper electrode 12 in the plasma treatment apparatus 1 of FIG. 1;

FIG. 3 is a fragmentary sectional view showing the structure of an upper electrode cover 31 appearing in FIG. 2;

FIG. 4 is a sectional view of an internal viewing tube in a plasma treatment apparatus according to a variation of the above embodiment;

FIG. 5 is a fragmentary sectional view showing the structure of an upper electrode cover 31 appearing in FIG. 4; and

FIG. 6 is a sectional view of an internal viewing tube provided in an upper electrode in a conventional plasma treatment apparatus.

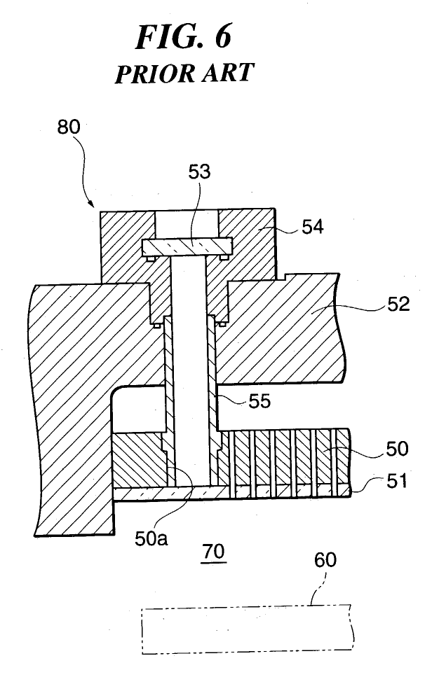

### DETAILED DESCRIPTION OF PREFERRED EMBODIMENTS

The present invention will now be described in detail with reference to the accompanying drawings showing preferred embodiments thereof.

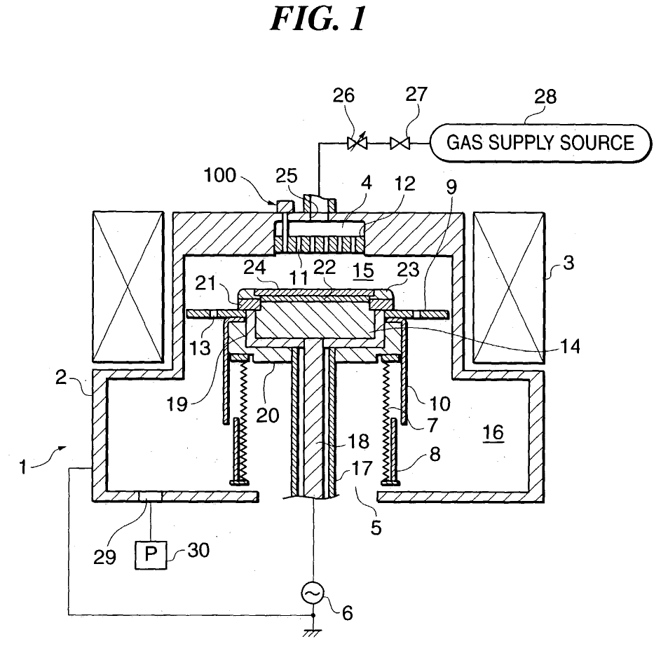

FIG. 1 is a schematic sectional view showing the construction of a plasma treatment apparatus according to an embodiment of the present invention.

In FIG. 1, the plasma treatment apparatus 1 has a plasma treatment vessel (vacuum vessel) 2 having a cylindrical lower portion having a predetermined diameter, and a cylindrical upper portion having a diameter smaller than that of the cylindrical lower portion. An annular permanent magnet 3 is fitted around the outside of the cylindrical upper portion of the plasma treatment vessel 2.

Moreover, the plasma treatment vessel 2 has a downwardly open recess 4 formed in an inner surface of a ceiling thereof, and has an opening 5 formed through a base of the lower portion thereof. The plasma treatment vessel 2 is made of an electrically conductive material.

In the plasma treatment vessel 2, the opening 5 in the base thereof is closed off by an exhaust plate 9 and so on via bellows 7 that are made of an electrically conductive material such as stainless steel and rise up from the base. The bellows 7 are protected by a first bellows cover 8 that is erected on the base of the plasma treatment vessel 2, and a second bellows cover 10 that is fixed to the exhaust plate 9 so as to fit around the first bellows cover 8. The recess 4 in the ceiling is closed off by an upper electrode 12 that has a plurality of through holes 11 formed therein.

The exhaust plate 9 is in the form of a ring-shaped disk having a plurality of vent holes 13 formed therein. The exhaust plate 9 has a disk-shaped lower electrode 14 fitted in a central portion thereof, and moreover partitions the inside of the plasma treatment vessel 2 into an internal chamber 15 in an upper portion thereof and an exhaust chamber 16 in a lower portion thereof. Together with an inside wall of the plasma treatment vessel 2, the upper electrode 12 and the exhaust plate 9 constitute the walls of the internal chamber 15.

A central portion of the lower electrode 14 is positioned below the upper electrode 12.

Moreover, on a lower surface of the lower electrode 14 are fixed a tubular member 17 that is made of an electrically conductive material such as oxidized Al and vertically extends from below the bottom of the plasma treatment vessel 2, and a raising/lowering shaft 18 that is housed inside the tubular member 17 and raises and lowers the lower electrode 14 in a vertical direction. The lower surface and a side surface of the lower electrode 14 are protected by an electrode protecting member 19, and furthermore a lower surface and a side surface of the electrode protecting member 19 are covered by an electrically conductive member 20. A high-frequency power source 6 is connected to the raising/lowering shaft 18.

An insulator ring 21 is disposed around the periphery of an upper surface of the lower electrode 14, and an electrostatic chuck 22 is disposed on the upper surface of the lower electrode 14 inside the insulator ring 21. Moreover, a focus ring 23 is disposed on the insulator ring 21, and a semiconductor wafer 24 is placed as an article to be treated on the electrostatic chuck 22 inside the focus ring 23, i.e. on a central portion of the lower electrode 14.

The plasma treatment vessel 2 has a gas supply port 25 formed in the ceiling thereof. A gas supply source 28 for supplying a treatment gas into the internal chamber 15 is connected to the gas supply port 25 via a flow regulating valve 26 and an opening/closing valve 27. Moreover, the plasma treatment vessel 2 has an exhaust port 29 formed in the base thereof, and a vacuum pump 30 for evacuating the internal chamber 15 is connected to the exhaust port 29.

With the plasma treatment apparatus 1 constructed as described above, when plasma treatment is carried out on the semiconductor wafer 24, first the raising/lowering shaft 18 is moved upward by means of a driving mechanism, not shown, thus moving the semiconductor wafer 24 to a predetermined position, and then high-frequency electrical power is applied to the lower electrode 14 using the high-frequency power source 6.

Next, the internal chamber 15 is evacuated to a predetermined vacuum atmosphere using the vacuum pump 30, and then the treatment gas, which contains a fluorocarbon gas, is introduced into the internal chamber 15 from the gas supply source 28 via the gas supply port 25, whereupon a glow discharge is generated due to the high-frequency electric field that has been formed between the upper electrode 12 and the lower electrode 14, and hence a plasma is produced on the semiconductor wafer 24 from the treatment gas, i.e. a plasma region is formed inside the internal chamber 15.

The upper electrode 12 disposed in the upper portion of the internal chamber 15 is comprised of an upper electrode main body made of a metal such as Al, and an upper electrode cover made of quartz that is joined to a lower surface of the upper electrode main body, for isolating the upper electrode main body from the plasma region formed in the internal chamber 15.

When etching a film such as an oxide film on the semiconductor wafer 24 using the plasma treatment apparatus 1, the inside of the internal chamber 15 is put into a medium pressure state, and a plasma of medium density is produced, whereby optimum radical control is made possible, and hence a suitable plasma state can be obtained. As a result, etching of the semiconductor wafer 24 with a high degree of stability and reproducibility can be realized.

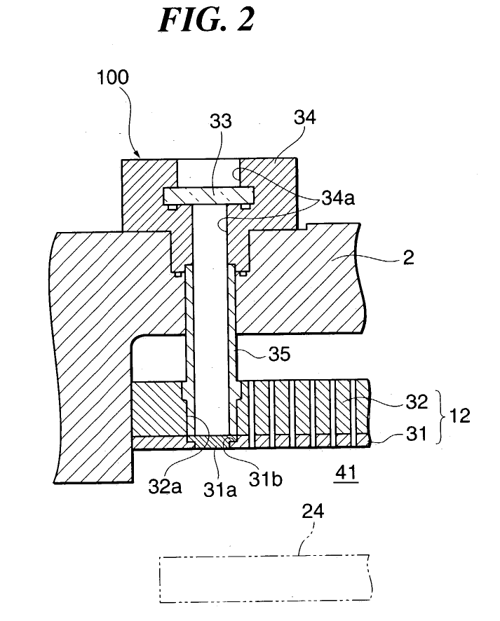

With the plasma treatment apparatus 1, the extent of progress of the etching is detected via an internal viewing tube provided in the upper electrode 12 as shown in FIG. 2, described below.

FIG. 2 is a sectional view of the internal viewing tube provided in the upper electrode 12 in the plasma apparatus 1 of FIG. 1.

In FIG. 2, the upper electrode cover 31 is joined to the lower surface of the upper electrode main body 32 so as to isolate the upper electrode main body 32 from the plasma region 41 formed inside the internal chamber 15. The internal viewing tube 100 is comprised of a sensor mount 34 that is provided on the vacuum vessel 2 above an opening 32a provided in the upper electrode main body 32, has a hole 34a formed in a central portion thereof, and has a sensor, not shown, mounted thereon, and a tubular member 35 that is provided in the vacuum vessel 2 with its lower end inserted in the opening 32a, and connects the opening 32a and the hole 34a of the sensor mount 34 together. An optical glass member 33 made of quartz or the like is fitted into the hole 34a of the sensor mount 34.

The upper electrode cover 31 has a hole 31b formed therein at a location corresponding to the opening 32a of the upper electrode main body 32, such that the hole 31b opens into the plasma region 41, and a window member 31a made of a transparent member is fitted into this hole 31b.

Light emitted by the sensor passes through the optical glass member 33 and enters the vacuum vessel 2. This light passes through the window member 31a that has been fitted into the hole 31b of the upper electrode cover 31, and reaches the semiconductor wafer 24. The light is reflected by the semiconductor wafer 24, and then the reflected light passes through the window member 31a of the upper electrode cover 31 and the optical glass member 33, and reaches the sensor.

The sensor detects changes in the intensity of the reflected light, thus detecting the extent of progress of the etching.

As the semiconductor wafer 24 plasma treatment (etching) progresses, once the time period of application of the high-frequency electric field has reached approximately 50 to 70 hours, fogging up of the window member 31a that has been fitted into the hole 31b of the upper electrode cover 31 occurs, and hence it becomes impossible for the sensor to detect changes in the intensity of the reflected light, and thus an error in sensor output is displayed on a display device, and maintenance of the upper electrode cover 31 is then carried out. The maintenance interval is determined based on the time period of application of the high-frequency electric field, and is approximately 70 hours in the case that the window member 31a is made of quartz.

Here, if fogging up of the window member 31a occurs, then because the window member 31a is fitted into the hole 31b of the upper electrode cover 31, it is not necessary to remove the whole of the upper electrode cover 31, but rather it is possible to remove and replace only the window member 31a, which is a separate body to the upper electrode cover 31, and hence the maintenance cost can be reduced.

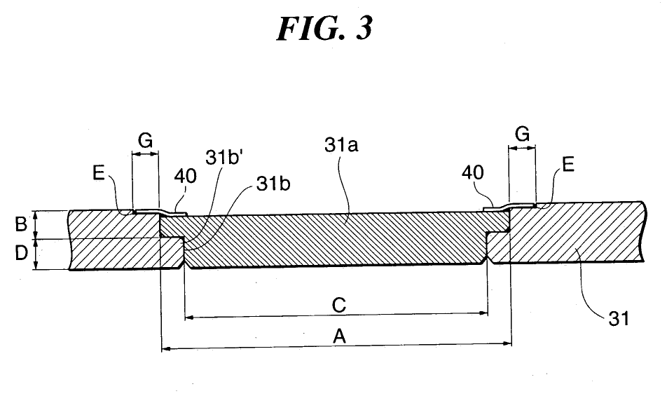

FIG. 3 is a fragmentary sectional view showing the structure of the upper electrode cover 31 appearing in FIG. 2.

In FIG. 3, the hole 31b of the upper electrode cover 31 has an annular stepped shoulder 31b′ and is comprised of a reduced diameter lower portion downward of the stepped shoulder 31b′ and an increased diameter upper portion upstream of the stepped shoulder 31b′. The reduced diameter lower portion has, for example, a diameter C of 14 mm and a thickness D of 1.5 mm, and the increased diameter upper portion has, for example, a diameter A of 17 mm and a thickness B of 1.45 mm. The window member 31a, which has a shape complementary to that of the hole 31b, is fitted into the hole 31b. Specifically, the window member 31a is comprised of a reduced diameter lower portion and an increased diameter upper portion such that the reduced diameter lower portion is fitted in the reduced diameter lower portion of the hole 31b and the increased diameter upper portion is fitted in the increased diameter upper portion of the hole 31b, respectively.

Moreover, a step having a width G of 1.5 mm and a depth of 0.15 mm is provided at an upper end peripheral edge E of the hole 31b of the upper electrode cover 31, and a Kapton tape 40 is stuck over the upper electrode cover 31 and the window member 31a from the upper end peripheral edge E over an upper end surface of the window member 31a, whereby the window member 31a is fixed to the upper electrode cover 31.

As described above, according to the present embodiment, the upper electrode cover 31 has a hole 31b formed therein at a location corresponding to the opening 32a of the upper electrode main body 32, and a transparent window member 31a is fitted into this hole 31b. As a result, if fogging up of the window member 31a occurs, then it is not necessary to remove the whole of the upper electrode cover 31, but rather it is easy to replace only the window member 31a, and hence the cost of maintenance of the plasma etching treatment apparatus 1 can be reduced.

According to the present embodiment, the hole 31b is constituted from a reduced diameter portion and an increased diameter portion, and the window member 31a has a shape complementary to that of the hole. As a result, the window member 31a can easily be fitted in from above.

A variation of the present embodiment will now be described.

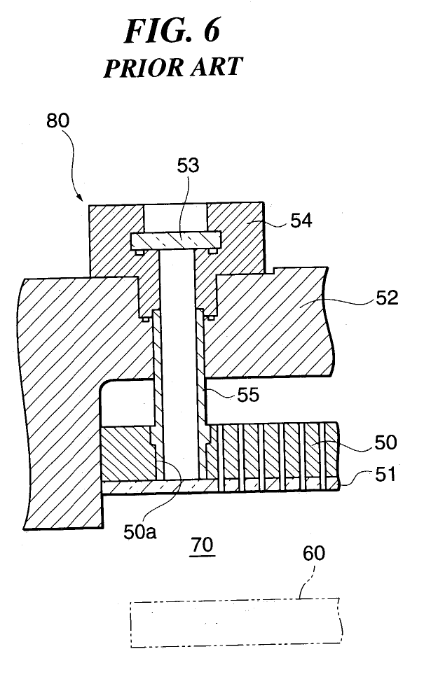

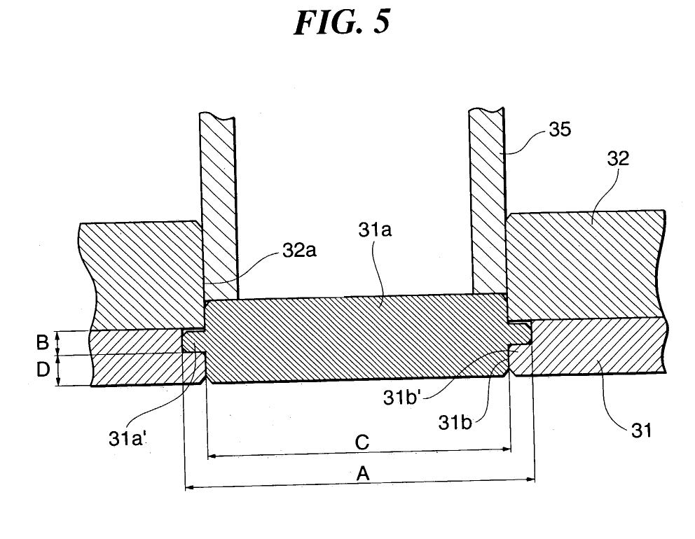

FIG. 4 is a sectional view of an internal viewing tube in a plasma treatment apparatus according to the variation of the present embodiment, and FIG. 5 is a fragmentary view showing the structure of an upper electrode cover 31 appearing in FIG. 4.

The plasma treatment apparatus according to the present variation has the same component elements and parts as the plasma treatment apparatus 1 of FIG. 1, and hence these component parts are designated by the same reference numerals as in FIG. 1, and description thereof is omitted.

As shown in FIGS. 4 and 5, the window member 31a has a vertically symmetrical shape. Specifically, the window member 31a has a solid cylindrical body which has an annular projection (increased diameter intermediate portion) 31a′ formed integrally therewith at approximately a center thereof in the vertical direction, a reduced diameter upper portion, and a reduced diameter lower portion. On the other hand, as is the case with the above described embodiment, the hole 31b of the upper electrode cover 31 has an annular stepped shoulder 31b′, and is comprised of a reduced diameter lower portion downward of the stepped shoulder 31b′ and an increased diameter upper portion upstream of the stepped shoulder 31b′. Further, the diameter of the opening 32a is approximately equal to that of the solid cylindrical body of the window member 31a, and an inner peripheral portion of the upper electrode main body 32 that defines the opening 32a and the annular stepped shoulder 31b′ of the hole 31b cooperate to define an annular channel therebetween. The window member 31a is mounted in the upper electrode cover 31 such that its reduced diameter upper portion is fitted in the opening 32a, its annular projection (increased diameter intermediate portion) 31a′ in the annular channel, and its reduced diameter lower portion in the reduced diameter lower portion of the hole 31b. As a result, the window member 31a can be installed into the hole 31b of the upper electrode cover 31 either way up, and hence the problem of installing the window member 31a upside down and thus having to reinstall the window member 31a can be eliminated, i.e. installation and removal of the window member 31a becomes easy.

Moreover, as shown in FIGS. 4 and 5, the tubular member 35 has an inside diameter that is smaller than the diameter C of the lower portion (reduced diameter portion) of the window member 31a, and hence a lower edge of the tubular member 35 is in contact with an upper end surface of the window member 31a. The window member 31a is thus fixed in place firmly by the lower edge of the upper electrode 35, the upper electrode main body 32, and the upper electrode cover 31. As a result, it is no longer necessary to provide a step (upper end peripheral edge) E and stick on a Kapton tape 40 as in FIGS. 2 and 3.

In the above described embodiment and variation, the material of the window member 31a is quartz, i.e. the same material as the upper electrode cover 31. However, there is no limitation thereto, but rather the material of the window member 31a may be a glass, for example a sapphire glass having high plasma resistance.

In the case that the material of the window member 31a is sapphire glass, the maintenance interval can be made to be approximately 270 hours or more, which is longer than in the case that the material of the window member 31a is quartz.

In the above described embodiment and variation, the material of the upper electrode cover 31 is quartz. However, there is no limitation thereto, but rather the material of the upper electrode cover 31 may be a glass, for example a sapphire glass having high plasma resistance.

Moreover, the dimensions of the window member 31a are not limited to being the values indicated in the present embodiment, but rather any dimensions may be used, so long as the dimensional accuracy is such that the plasma does not leak.

What is claimed is:

1. A plasma treatment apparatus comprising:
a vacuum vessel that houses an article to be treated and into which a treatment gas is introduced;
a lower electrode that is provided inside said vacuum vessel and onto which is placed the article to be treated;
an upper electrode main body that is provided above said lower electrode to form a plasma region in said vacuum vessel, said upper electrode main body having formed therein an opening through which passes light for detecting an extent of progress of plasma treatment of the article to be treated in the plasma region;
an upper electrode cover that is joined to a lower surface of said upper electrode main body, said upper electrode cover having formed therein a hole at a location corresponding to the opening of said upper electrode main body; and
a window member fitted in the hole of said upper electrode cover.

2. An upper electrode cover for a plasma treatment apparatus, the plasma treatment apparatus comprising a vacuum vessel that houses an article to be treated and into which a treatment gas is introduced a lower electrode that is provided inside the vacuum vessel and onto which is placed the article to be treated, and an upper electrode main body that is provided above the lower electrode to form a plasma region in the vacuum vessel, the upper electrode main body having formed therein an opening through which passes light for detecting an extent of progress of plasma treatment of the article to be treated in the plasma region,
wherein the upper electrode cover has formed therein a hole in which a window member is to be fitted, at a location corresponding to the opening in the upper electrode main body, the hole having a shape complementary to a shape of the window member.

3. An upper electrode cover as claimed in claim 2, wherein the hole has a lower portion having a reduced diameter and an upper portion having an increased diameter.

4. An upper electrode cover as claimed in claim 2, wherein the hole opens into the plasma region.

5. An upper electrode cover as claimed in claim 2, which is made of quartz.

6. An upper electrode cover window member for a plasma treatment apparatus, the plasma treatment apparatus comprising a vacuum vessel that houses an article to be treated and into which a treatment gas is introduced a lower electrode that is provided inside the vacuum vessel and onto which is placed the article to be treated, an upper electrode main body that is provided above the lower electrode to form a plasma region in the vacuum vessel, the upper electrode main body having formed therein an opening through which passes light for detecting an extent of progress of plasma treatment of the article to be treated in the plasma region, and an upper electrode cover that is joined to a lower surface of the upper electrode main body,
wherein the upper electrode cover window member comprises a transparent member that has at least in part a shape complementary to a shape of a hole formed in the upper electrode cover at a location corresponding to the opening in the upper electrode main body such that the upper electrode cover window member can be fitted in the hole.

7. An upper electrode cover window member as claimed in claim 6, wherein the hole has a lower portion having a reduced diameter and an upper portion having an increased diameter, and the upper electrode cover window member has a lower portion having a reduced diameter and an upper portion having an increased diameter that can be fitted in the lower portion and upper portion of the hole, respectively.

8. An upper electrode cover window member as claimed in claim 6, wherein the hole has a lower portion having a reduced diameter and an upper portion having an increased diameter, and the upper electrode cover window member presents a vertically symmetrical shape having a lower portion having a reduced diameter, an intermediate portion having an increased diameter, and an upper portion having a reduced diameter that can be fitted in the lower portion of the hole, the opening in the upper electrode main body, and the upper portion of the hole, respectively.

9. An upper electrode cover window member as claimed in claim 6, which is made of quartz.

10. An upper electrode cover window member as claimed in claim 6, which is made of sapphire.
